(19) United States
(12) Patent Application Publication
(10) Pub. No.: US 2006/0202198 A1
(43) Pub. Date: Sep. 14, 2006

(54) Integrated circuit, and method for the production of an integrated circuit

(76) Inventors: Marcus Halik, Erlangen (DE); Hagen Klauk, Stuttgart (DE); Guenter Schmid, Hemhofen (DE); Andreas Walter, Dresden (DE); Ute Zschieschang, Stuttgart (DE)

Correspondence Address: SLATER & MATSIL LLP, 17950 PRESTON ROAD, SUITE 1000, DALLAS, TX, 75252, US

(21) Appl. No.: 11/364,847

(22) Filed: Feb. 28, 2006

Related U.S. Application Data
(63) Continuation of application No. PCT/DE04/01904, filed on Aug. 24, 2004.

(30) Foreign Application Priority Data
Aug. 29, 2003 (DE) 103 40 609.3

(51) Int. Cl. H01L 29/08

(52) U.S. Cl. 257/40

(57) ABSTRACT

Embodiments of the invention relate to an integrated circuit comprising an organic semiconductor, particularly an organic field effect transistor (OFET) that is provided with a dielectric layer. The integrated circuit is produced by means of a polymer formulation consisting of a) 100 parts of at least one crosslinkable basic polymer, b) 10 to 20 parts of at least one electrophilic crosslinking component, c) 1 to 10 parts of at least one thermal acid catalyst that generates an activating proton at temperatures ranging from 100 to 150° C., dissolved in d) at least one solvent. Other embodiments of the invention further relate to a method for producing an integrated circuit, which makes it possible to produce integrated circuits comprising dielectric layers, especially for OFET's at low temperatures.

This application is a continuation of co-pending International Application No. PCT/DE2004/001904, filed Aug. 24, 2004, which designated the United States and was not published in English, and which is based on German Application No. 103 40 609.3, filed Aug. 29, 2003, both of which applications are incorporated herein by reference.

### TECHNICAL FIELD

The invention relates to an integrated circuit and a method for producing an integrated circuit comprising an organic semiconductor.

### BACKGROUND

Systems comprising integrated circuits based on organic field effect transistors (OFET) constitute a promising technology in the mass application sector of economical electronics. A field effect transistor is considered to be organic particularly if the semiconducting layer is produced from an organic material.

Since it is possible to build up complex circuits using OFETs, there are numerous potential applications. Thus, for example, the introduction of RF-ID (radio frequency identification) systems based on this technology is considered as a potential replacement for the bar code, which is susceptible to faults and can be used only in direct visual contact with the scanner.

In particular, circuits on flexible substrates, which can be produced in large quantities in roll-to-roll processes, are of interest here.

Owing to the thermal distortion of most suitable economical substrates (e.g., polyethylene terephthalate (PET), polyethylene naphthalate (PEN)), there is an upper temperature limit of 130-150° C. for the production of such flexible substrates. Under certain preconditions, for example a thermal pretreatment of the substrate, this temperature limit can be increased to 200° C. but with the restriction that, although the distortion of the substrate is reduced, it is not prevented.

A critical process step in the case of electronic components is the deposition of the dielectric layer, in particular the gate dielectric layer, of an OFET. The quality of the dielectrics in OFETs should meet very high requirements with regard to the thermal, chemical, mechanical and electrical properties.

Silicon dioxide (SiO₂) currently is the most frequently used gate dielectric in OFETs, based on the wide availability in semiconductor technology. Thus, transistor structures in which a doped silicon wafer serves as the gate electrode, and thermal SiO₂ grown thereon forms the gate dielectric are described. This SiO₂ is produced at temperatures of about 800-1000° C. Other processes (e.g., CVD) for the deposition of SiO₂ on various substrates likewise operate at temperatures above 400° C. A group at PennState University has developed a process (ion beam sputtering) that makes it possible to deposit a high-quality SiO₂ at process temperatures of 80° C. This is described in the articles by C. D. Sheraw, J. A. Nichols, D. J. Gundlach, J. R. Huang, C. C. Kuo, H. Klauk, T. N. Jackson, M. G. Kane, J. Campi, F. P. Cuomo and B. K. Greening, “Fast Organic Circuits on Polymeric Substrates,” Electron Devices Meet., 619 (2000), and C. D. Sheraw, L. Zhou, J. R. Huang, D. J. Gundlach, T. N. Jackson, M. G. Kane, I. G. Hill, M. S. Hammond, J. Campi, B. K. Greening, J. Francl and J. West, “Organic thin-film transistor driven polymer-dispersed liquid crystal displays on flexible polymeric substrates,” Appl. Phys. Lett. 80, 1088 (2002).

However, the high process costs and the low throughput are disadvantageous for mass-produced products.

It is also known that inorganic nitrides, such as, for example, SiNₓ′, TaNₓ, can be used. Similarly to the preparation of inorganic oxides, the deposits of inorganic nitrides require high temperatures or high process costs. This is described, for example, in the article by B. K. Crone, A. Dodabalapur, R. Sarpeshkar, R. W. Filas, Y. Y. Lin, Z. Bao, J. H. O'Neill, W. Li and H. E. Katz, “Design and fabrication of organic complementary circuits,” J. Appl. Phys. 89, 5125 (2001).

It is also known that hybrid solutions (spin on glass) can be used. Organic siloxanes, which can be prepared from a solution and can be converted into “glass-like” layers by thermal conversion, were described. The conversion into SiO₂ is effected either at high temperatures (about 400° C.) or takes place only partly, which results in a reduced transistor quality (in this context, cf. the article by Z. Bao, V. Kuck, J. A. Rogers and M. A. Paczkowski, “Silsequioxane Resins as High-Performance Solution Processible Electric Materials for Organic Transistor Applications,” Adv. Funct. Mater., 12, 526 (2002).

In addition, organic polymers, such as poly-4-vinylphenol (PVP), poly-4-vinylphenol-co-2-hydroxyethyl methacrylate or polyimide (PI), have already been used. These polymers are distinguished by their comparatively simple processibility. Thus, they can be used, for example, from solution for spin coating or printing. The outstanding dielectric properties of such materials have already been demonstrated (cf. article by H. Klauk, M. Halik, U. Zschieschang, G. Schmid, W. Radlik and W. Weber, “High-mobility polymer gate dielectric pentacene thin film transistors,” J. Appl. Phys., Vol. 92, No. 9 (November 2002)).

It has also already been possible to demonstrate applications in ICs, the required chemical and mechanical stabilities of the dielectric layers for the structuring thereof and the structuring of the subsequent source-drain layer having been achieved by crosslinking of the polymers (cf. article by M. Halik, H. Klauk, U. Zschieschang, T. Kriem, G. Schmid and W. Radlik, “Fully patterned all-organic thin-film transistors,” Appl. Phys. Lett., 81, 289 (2002)).

However, this crosslinking is effected at temperatures of 200° C, which is problematic for the production of flexible substrates having a large area.

### SUMMARY OF THE INVENTION

One aspect of the present invention provides an integrated circuit comprising an organic semiconductor and a method in which the production of dielectric layers of OEFTs is possible at low temperatures.

According to a preferred embodiment of the invention, the integrated circuit comprising an organic semiconductor can be produced from a polymer formulation consisting of:

a) 100 parts of at least one crosslinkable base polymer;

b) 10 to 20 parts of at least one electrophilic crosslinking component;

c) 1 to 10 parts of at least one thermal acid catalyst, which generates an activating proton at temperatures between 100-150° C.; and

d) at least one solvent.

The integrated circuits according to preferred embodiments of the invention are in particular OFETs having organic layers, which generally have outstanding dielectric properties. Owing to the specific polymer formulation used, the integrated circuits can be produced in a simple manner at low temperatures (e.g., up to 150° C.). This polymer formulation can also be used in principle in combination with other electronic components.

It is advantageous if at least one base polymer is a phenol-containing polymer or copolymer, in particular poly-4-vinylphenol, poly-4-vinylphenol-co-2-hydroxyethyl methacrylate or poly-4-vinylphenol-co-methyl methacrylate.

Advantageously, at least one electrophilic crosslinking component is a di- or tribenzyl alcohol compound, in particular 4-hydroxymethylbenzyl alcohol.

It is advantageous if at least one crosslinking component has one of the following structures:

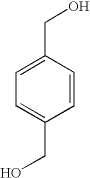

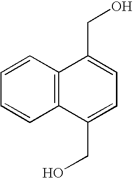

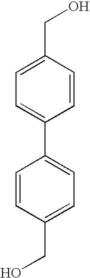

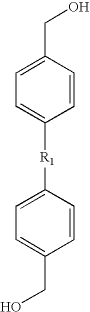

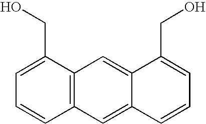

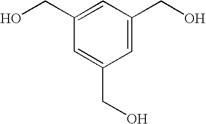

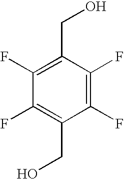

The following is true for R₁: —O—, —S—, —SO₂—, —S₂—, —(CH₂)ₓ—, in which x=1-10, and additionally:

—C═C—
—C≡C—
—(CF₂)_{y}—
y = 1-10

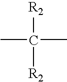

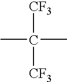

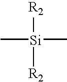

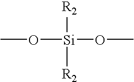

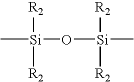

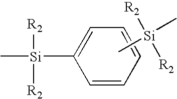

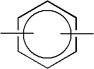

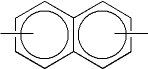

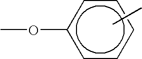

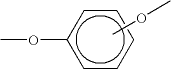

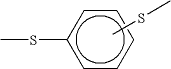

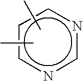

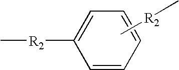

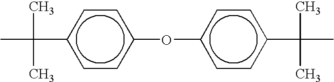

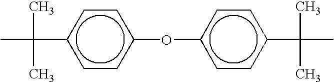

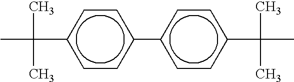

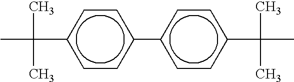

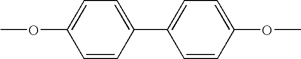

The following is true for R₂ alkyl having 1 to 10 carbon atoms or aryl

Advantageously, the thermal acid catalyst used may be at least one sulfonic acid, in particular 4-toluenesulfonic acid, as this is able to transfer a proton to the hydroxyl group of a benzyl alcohol, at below 150° C.

Advantageous solvents are an alcohol, in particular n-butanol, propylene glycol monomethyl ethyl acetate (PGMEA), dioxane, N-methylpyrrolidone (NMP), γ-butyrolactone, xylene or a mixture.

For good processibility, it is advantageous if the proportion of base polymer, crosslinking component and acid generator is a proportion between 5 and 20% by mass.

According to a preferred embodiment of the invention, a method for producing an integrated circuit, in particular of an OFET, having a dielectric layer comprises a polymer formulation applied to a substrate, in particular having a prestructured gate electrode, and a crosslinking reaction for the formation of the gate dielectric layer is carried out at between 100 and 150° C.

For the production of an OFET, at least one further structuring for producing the OFET is then advantageously carried out.

The polymer formulation is advantageously applied by spin coating, printing or spraying.

The crosslinking reaction is advantageously effected under an inert gas atmosphere, in particular an N₂ atmosphere.

After the application of the polymer formulation and the production of the polymer film, it is advantageous to carry out drying, in particular at 100° C.

For the production of the OFET, it is then advantageous to apply a source-drain layer to the gate dielectric layer.

Finally, it is advantageous if an active layer for the formation of an OFET, in particular comprising the semiconducting pentacene, is applied to the source-drain layer. A passivating layer is advantageously arranged on the active layer.

### DESCRIPTION OF THE DRAWINGS

The invention is explained in more detail below for a plurality of embodiments with reference to the figures of the drawings.

FIG. 1 shows a schematic diagram of an organic field effect transistor;

FIG. 2 shows an example of a crosslinking reaction of a polymeric gate dielectric comprising PVP and 4-hydroxymethylbenzyl alcohol as a crosslinking agent;

FIG. 3a shows a family of output characteristics of an OFET comprising an electrophilically crosslinked gate dielectric;

FIG. 3b shows a family of transmission characteristics of an OFET comprising an electrophilically crosslinked gate dielectric; and

FIG. 4 shows a trace of an oscilloscope image of the characteristics of a 5-stage ring oscillator.

The following list of reference symbols can be used in conjunction with the figures:

1 Substrate

2 Gate electrode

3 Gate dielectric layer

4a Drain layer

4b Source layer

5 Active layer

6 Passivating layer

### DETAILED DESCRIPTION OF ILLUSTRATIVE EMBODIMENTS

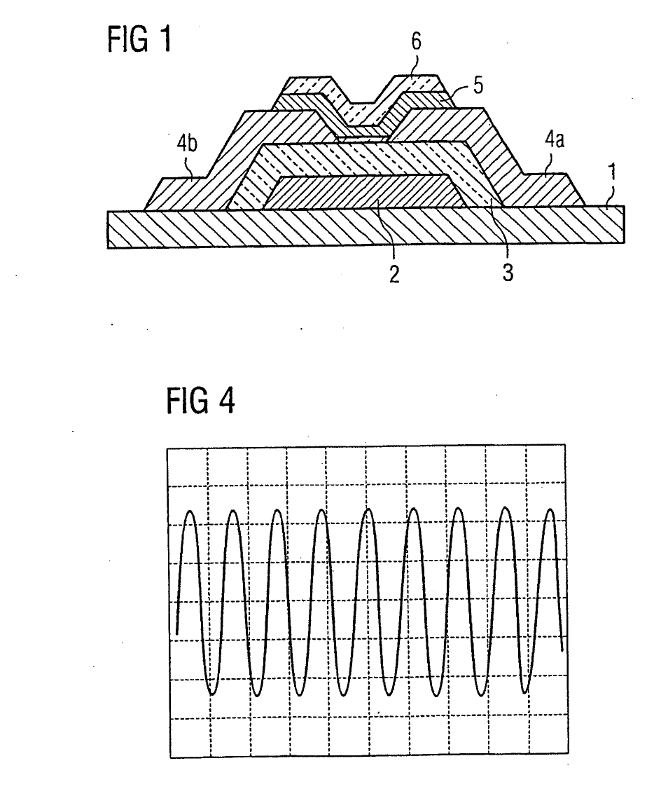

OFETs are electronic components that consist of a plurality of layers, all of which have been structured in order to generate integrated circuits by connections of individual layers. FIG. 1 shows the fundamental structure of an OFET transistor in a bottom contact architecture.

A gate electrode 2, which is covered by a gate dielectric layer 3, is arranged on a substrate 1. As will be explained later, in an embodiment of the process according to the invention the substrate 1 with the gate electrode 2 already arranged thereon constitutes the starting material on which the gate dielectric layer 3 is applied. A drain layer 4a and a source layer 4b, both of which are connected to the active semiconducting layer 5, are arranged on the gate dielectric layer 3. A passivating layer 6 is arranged above the active-layer 5.

The deposition and processing of the gate dielectric layer 3 are described herein below.

The circuits according to embodiments of the invention and the production thereof generally solve the problem of the provision of OFETs having gate dielectric layers, in particular with organic ICs having outstanding mechanical, chemical and electrical properties in combination with low process temperatures.

An OFET has a dielectric layer that can be produced from a mixture (polymer formulation) comprising in principle four components: a base polymer, a crosslinking component, a thermal acid generator and a solvent. An embodiment of the circuit according to the invention, which is mentioned here by way of example, has a polymer formulation comprising the following components:

a) PVP as the crosslinkable base polymer;

b) 4-hydroxymethylbenzyl alcohol as an electrophilic crosslinking component;

c) 4-toluene-sulfonic acid which generates an activating proton at temperatures between 100-150° C. as the acid catalyst; and

d) e.g. alcohols, PGMEA as the solvent.

This polymer formulation is applied to a correspondingly prepared substrate 1 (gate structures 2 have already been defined on the substrate 1). The polymer formulation can be applied, for example, by printing, spin coating or spray coating. By subsequent drying at moderate temperatures (about 100° C.), the polymer formulation is fixed on the substrate and subsequently converted into its final structure in a thermal crosslinking step.

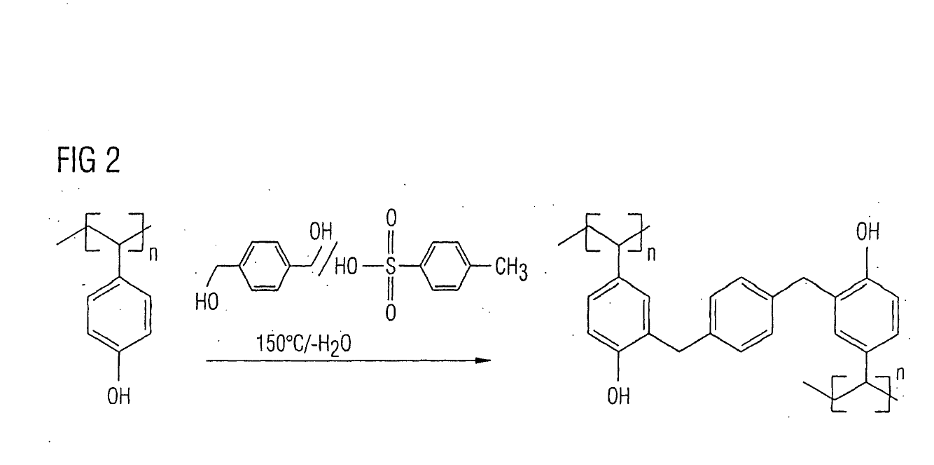

FIG. 2 shows schematically how PVP is crosslinked with 4-hydroxymethylbenzyl alcohol at a temperature of 150° C. with elimination of water. Alternatively, the compounds shown below can also be use as electrophilic crosslinker:

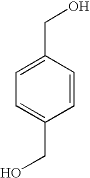

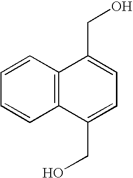

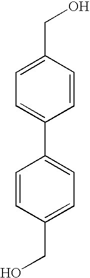

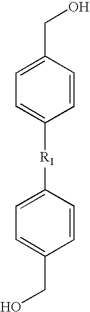

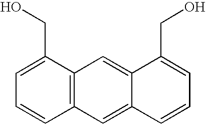

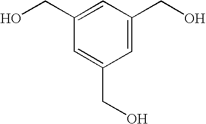

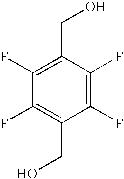

The following is true for R₁: —O—, —S—, —SOₓ—, —Sₓ——(CH₂)ₓ— in which x=1-10, and additionally:

—C═C—
—C≡C—
—(CF₂)_{y}—
y = 1-10

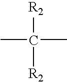

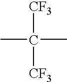

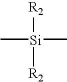

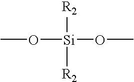

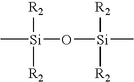

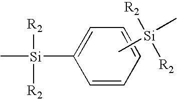

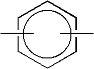

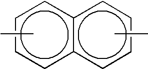

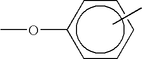

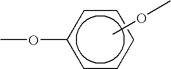

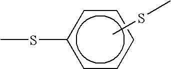

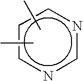

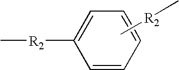

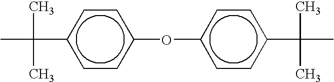

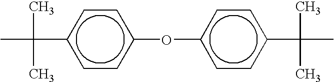

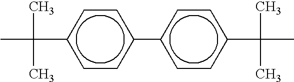

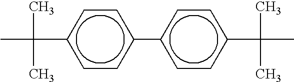

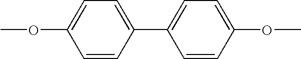

The following is true for R₂: alkyl having 1 to 10 carbon atoms or aryl

A step for the production of gate dielectric layers 3 with the required properties is in this case this crosslinking reaction and the initiation thereof at temperatures that are not critical for the substrate. These are temperatures from 20° C. to a maximum of 150° C.

The use of the process reduces the required crosslinking temperature by more than 50° C. compared with the methods known to date (cf. article by Halik et al. (2002)).

The base polymer determines the fundamental properties of the gate dielectric layer 3. Suitable base polymers are in principle all phenol-containing polymers and copolymers thereof, for example, poly-4-vinylphenol, poly-4-vinylphenol-co-2-hydroxyethyl methacrylate or poly-4-vinylphenol-co-methyl methacrylate.

By the choice of the crosslinking component and the concentration thereof in the polymer formulation, the mechanical properties of the polymer layer and the resistance to chemicals can be controlled.

By the choice of the thermal acid catalyst, the temperature for the initiation of the crosslinking reaction can be controlled.

The choice of the solvent determines the film formation properties of the formulation.

Two polymer formulations that differ only in the proportion of the crosslinking agent are described below as examples.

Formulation 1 is a 10% strength solution in propylene glycol monomethyl ether acetate (PGMEA). 100 pars of base polymer, 10 parts of crosslinking agent and 2.5 parts of acid generator are present.

A mixture of 2 g of PVP (MW about 20,000) as base polymer and 200 mg of 4-hydroxymethylbenzyl alcohol as crosslinking agent are dissolved in 20.5 g of PGMEA as solvent on a shaking apparatus (about 3 hours).

Thereafter, 50 mg of 4-toluene-sulfonic acid as an acid generator are added and the total solution is shaken for a further hour. Before use, the polymer solution is filtered through a 0.2 μm filter.

Formulation 2 is a 10% strength solution in PGMEA. 100 pars of base polymer, 20 parts of crosslinking agent and 2.5 parts of acid generator are present. The proportion of crosslinking agent is therefore twice as high as in the formulation 1.

A mixture of 2 g of PVP (MW about 20,000) as base polymer and 400 mg of 4-hydroxymethylbenzyl alcohol as crosslinking agent are dissolved in 20.5 g of PGMEA as solvent on a shaking apparatus (about 3 hours). Thereafter, 50 mg of 4-toluene-sulfonic acid as an acid generator are added and the total solution is shaken for a further hour. Before use, the polymer solution is filtered through a 0.2 μm filter.

Film Preparation:

2 ml of the formulation 1 are applied by means of a spin coater at 4000 rpm for 22 seconds to a prepared substrate (PEN (polyethylene naphthalate) having Ti gate structures). Thereafter, drying is effected at 100° C. for 2 min on a hotplate. The crosslinking reaction is effected at 150° C. in an oven under a 400 mbar N₂ atmosphere. The film preparation for formulation 2 is effected analogously.

Structuring of the Gate Dielectric Layer:

A photoresist is applied to the crosslinked polymer layer (gate dielectric layer 3)(S 1813; 3000 rpm; 30 s) and dried for 2 minutes at 100° C. Thereafter, the subsequent contact holes are defined by means of the exposure and development of the photo resist. The opening of the contact holes is effected by means of oxygen plasma (45 s twice at 100 W).

The source-drain layer 4 is then deposited and structured by standard methods (30 nm Au applied thermally by vapor deposition, photolithographic structuring and wet chemical etching with I₂/KI solution).

The layer thickness of the gate dielectric layers 2 is 210 nm for formulation 1. The roughness of the layer is 0.5 nm on 50 μm.

The layer thickness of the gate dielectric layers is 230 nm for formulation 2. The roughness of the layer is 0.6 m on 50 μm.

The transistors or circuits are completed by applying the active component 5 (in this case pentacene) thermally by vapor deposition. Except for the passivating layer 6, the structure of an OFET according to FIG. 1 is thus produced.

Here, embodiments for a polymer formulation and the use thereof for the production of gate dielectric layers 3 at low temperatures for use in integrated circuits based on OFETs are described. These gate dielectric layers 3 generally are distinguished by outstanding thermal, chemical, mechanical and electrical properties in addition to the low process temperature for the production thereof.

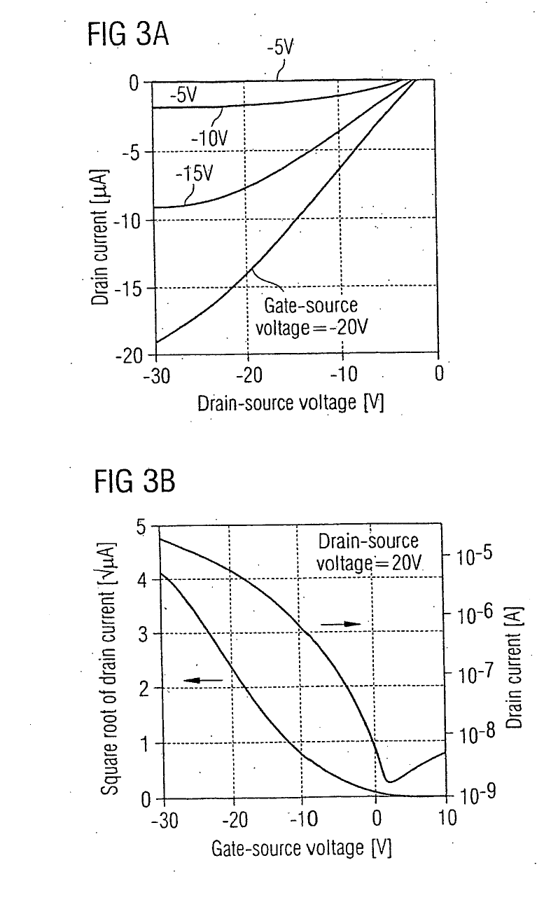

FIG. 3a shows a family of output characteristics of a pentacene OFET comprising an electrophilically crosslinked gate dielectric. FIG. 3b shows, for the same structure, the transmission characteristics of an OFET (μ=0.5 cm²/Vs, on/off ratio=10⁴). In FIG. 4, a trace of an oscilloscope diagram is reproduced. The characteristic of a 5-stage ring oscillator is shown, the ring oscillator operating with a signal lag of 120 μsec per stage.

The invention is not limited in its execution to the above-mentioned preferred embodiments.

Rather, a number of variants that make use of the apparatus according to the invention and the method according to the invention also in versions of fundamentally different types is conceivable.

What is claimed is:

1. An integrated circuit comprising an organic field effect transistor (OFET), having a dielectric layer formed from a polymer formulation comprising:
about 100 pars of at least one crosslinkable base polymer;
about 10 to 20 parts of at least one electrophilic crosslinking component; and
about 1 to 10 parts of at least one thermal acid catalyst, which generates an activating proton at temperatures between about 100-150° C. dissolved in at least one solvent.

2. The integrated circuit as claimed in claim 1, wherein at least one base polymer is a phenol-containing polymer or copolymer.

3. The integrated circuit as claimed in claim 2, wherein the at least one base polymer is poly-4-vinylphenol, poly-4-vinylphenol-co-2-hydroxyethyl methacrylate or poly-4-vinylphenol-co-methyl methacrylate.

4. The integrated circuit as claimed in claim 1, wherein the at least one thermal acid catalyst is a sulfonic acid.

5. The integrated circuit as claimed in claim 4, wherein the at least one thermal acid catalyst is a 4-toluenesulfonic acid.

6. The integrated circuit as claimed in claim 1, wherein the at least one electrophilic crosslinking component is a di- or tribenzyl alcohol compound.

7. The integrated circuit as claimed in claim 6, wherein the at least one electrophilic crosslinking component is 4-hydroxymethylbenzyl alcohol.

8. The integrated circuit as claimed in claim 1, wherein at least one crosslinking component has the following structures: 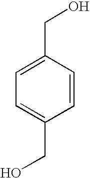 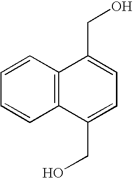 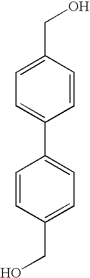 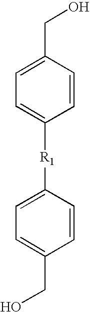 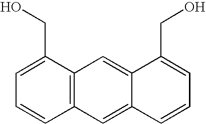 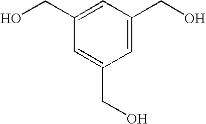 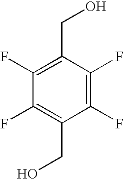
wherein R₁ is: —O—, —S—, —SO₂—, —S₂—, —(CH₂)ₓ—, in which x=1-10, and additionally:
—C═C—
—C≡C—
—(CF₂)_{y}—
y = 1-10 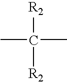 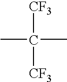 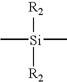 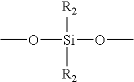 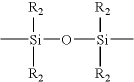 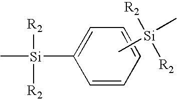 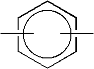 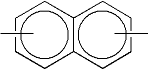 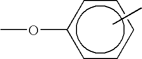 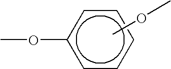 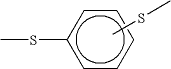 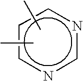 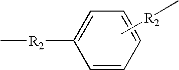 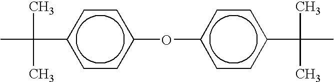 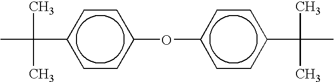 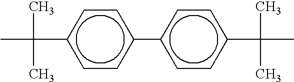 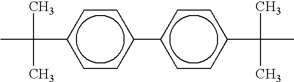 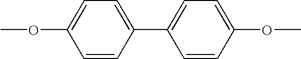
wherein R₂ is: alkyl having 1 to 10 carbon atoms or aryl.

9. The integrated circuit as claimed in claim 1, wherein the at least one solvent is an alcohol.

10. The integrated circuit as claimed in claim 9, wherein the at least one solvent is n-butanol, propylene glycol monomethyl ether acetate (PGMEA), dioxane, N-methylpyrolidone (NMP), γ-butyrolactone, xylene or a mixture thereof.

11. The integrated circuit as claimed in claim 1, further comprising a proportion of the base polymer, the crosslinking component and the acid catalyst of from 5 to 20% by mass.

12. A method for producing an integrated circuit comprising an OFET having a dielectric layer, the method comprising:
applying a polymer formulation to a substrate having a prestructured gate electrode, wherein the polymer formation comprises about 100 pars of at least one crosslinkable base polymer, about 10 to 20 parts of at least one electrophilic crosslinking component, and about 1 to 10 parts of at least one thermal acid catalyst, which generates an activating proton at temperatures between about 100-150° C. dissolved in at least one solvent; and
effecting a crosslinking reaction for the formation of the gate dielectric layer at between about 100 and 150° C.

13. The method as claimed in claim 12, wherein, after the crosslinking reaction, at least one further structuring for producing the OFET is effected.

14. The method as claimed in claim 12, wherein the polymer formulation is applied by spin coating, printing or spraying.

15. The method as claimed in claim 12, wherein the crosslinking reaction is effected under an inert gas atmosphere, comprising N₂.

16. The method as claimed in claim 12, wherein, after the application of the polymer formulation, drying is effected.

17. The method as claimed in claim 16, wherein the polymer formulation is dried at about 100° C.

18. The method as claimed in claim 12, wherein a source-drain layer is applied to the gate dielectric layer.

19. The method as claimed in claim 18, wherein an active layer for the formation of an OFET, the active layer comprising pentacene, is applied to the source-drain layer.

20. The method as claimed in claim 19, wherein a passivating layer is arranged on the active layer.
